(19) United States
(12) Patent Application Publication
(10) Pub. No.: US 2026/0113031 A1
(43) Pub. Date: Apr. 23, 2026

(54) SEMICONDUCTOR DEVICE

(71) Applicant: Renesas Electronics Corporation, Tokyo (JP)

(72) Inventors: Akihiro NAKAHARA, Tokyo (JP); Tomoaki OTA, Tokyo (JP)

(73) Assignee: Renesas Electronics Corporation, Tokyo (JP)

(21) Appl. No.: 19/364,334

(22) Filed: Oct. 21, 2025

(30) Foreign Application Priority Data
Oct. 23, 2024 (JP) 2024-186845

(51) Int. Cl. H03K 17/687; G01K 3/00

(52) U.S. Cl. CPC H03K 17/6871; G01K 3/005

(57) ABSTRACT

A semiconductor device capable of generating a correct over-temperature detection signal for an output transistor even when a revers current from the load to the output transistor occurs. A temperature sensing diode is formed on a semiconductor substrate adjacent to the power transistor, generating a forward voltage with a magnitude reflecting a temperature of the output transistor. An over-temperature detection circuit detects over-temperature of the power transistor by comparing a magnitude of the forward voltage with a reference voltage and asserts an over-temperature detection signal. A reverse current detection circuit detects an occurrence of the reverse current in the power transistor and asserts a reverse current detection signal during occurrence period. The semiconductor device uses the reverse current detection signal to perform processes such as masking the over-temperature detection signal.

### CROSS-REFERENCE TO RELATED APPLICATION

This application claims priority under 35 U.S.C. §119 to Japanese Patent Application No. 2024-186845 filed on October 23, 2024. The disclosure of Japanese Patent Application No. 2024-186845, including the specification, drawings and abstract is incorporated herein by reference in its entirety.

### BACKGROUND

The present invention relates to a semiconductor device, specifically to a semiconductor device that supplies power to a load coupled externally.

There are disclosed techniques listed below.

[Patent Document 1] Japanese Unexamined Patent Application Publication No. 2014-60581

Patent Document 1 discloses a load driving circuit capable of detecting overcurrent and over-temperature to perform appropriate protective operations. This load driving circuit includes an output transistor, an overcurrent detection circuit and an over-temperature detection circuit that detect overcurrent and over-temperature in the output transistor, respectively, a cutoff circuit that controls the output transistor to turn off in response to the detection of overcurrent or over-temperature, and a holding circuit. The holding circuit retains the overcurrent detection signal and subsequently releases the retention of the overcurrent detection signal in response to a signal from outside. The over-temperature detection circuit detects over-temperature when the detected temperature exceeds a predetermined temperature and subsequently cancels the over-temperature detection state when the temperature falls below the predetermined temperature.

### SUMMARY

For example, as shown in Patent Document 1, a semiconductor device equipped with an output transistor and an over-temperature detection circuit is known. The over-temperature detection circuit typically uses a temperature sensing diode that generates a forward voltage corresponding to the temperature to detect the temperature of the output transistor. The temperature sensing diode can be formed adjacent to the output transistor on the semiconductor substrate to detect the temperature of the output transistor with high accuracy.

On the other hand, when power is intermittently supplied to a load using such a semiconductor device, a reverse current may flow from the load to the output transistor due to power fluctuations. This reverse current can occur, for example, when driving capacitive or inductive loads. Another example is when the load is a generator, and ripple current generated by rectification can also become reverse current. However, when reverse current flows, a bias current to the temperature sensing diode adjacent to the output transistor may change due to parasitic currents caused by the reverse current. As a result, the over-temperature detection circuit may generate an erroneous over-temperature detection signal.

The embodiments described later have been made in view of such circumstances, and other problems and novel features will become apparent from the description of this specification and the accompanying drawings.

A semiconductor device according to one embodiment comprises an output transistor formed on a semiconductor substrate, coupled between a power supply terminal and a power output terminal, and configured to supply power to a load coupled to the power output terminal when the output transistor is controlled to be on, a temperature sensing diode formed on the semiconductor substrate adjacent to the output transistor, and configured to generate a forward voltage with a magnitude reflecting a temperature of the output transistor, a bias circuit configured to supply a bias current to the temperature sensing diode, an over-temperature detection circuit configured to detect an over-temperature of the output transistor by comparing a magnitude of the forward voltage with a threshold voltage, and configured to assert a first over-temperature detection signal when the over-temperature is detected, a reverse current detection circuit configured to detect an occurrence of a reverse current flowing from the power output terminal to the power supply terminal, and configured to assert a reverse current detection signal during a period the reverse current occurs, and a mask circuit configured to input the reverse current detection signal and the first over-temperature detection signal, and configured to generate a second over-temperature detection signal with a negated level during an assertion period of the reverse current detection signal.

According to the embodiment, even if reverse current occurs from the load to the output transistor, a correct over-temperature detection signal targeting the output transistor can be generated.

### BRIEF DESCRIPTION OF THE DRAWINGS

FIG. 1 is a circuit diagram showing a configuration example of a main part of a semiconductor device according to a first embodiment.

FIG. 2 is a schematic diagram showing a layout configuration example of the semiconductor device in FIG. 1.

FIG. 3 is a cross-sectional view showing a configuration example between A-A' in FIG. 2.

FIG. 4 is a cross-sectional view showing a configuration example between C-C' in FIG. 2.

FIG. 5A is a timing chart showing an operation example when there is no over-temperature state and no reverse current flows in the semiconductor device shown in FIG. 1.

FIG. 5B is a timing chart showing an operation example when there is no over-temperature state and reverse current flows in the semiconductor device shown in FIG. 1.

FIG. 6 is a circuit block diagram showing a configuration example of an electronic control system (ECU) to which the semiconductor device shown in FIG. 1 is applied.

FIG. 7 is a schematic diagram showing a configuration example of a vehicle equipped with the electronic control system (ECU) shown in FIG. 6.

FIG. 8 is a circuit diagram showing a configuration example of the main part of a semiconductor device according to a second embodiment.

FIG. 9 is a timing chart showing an operation example when there is no over-temperature state and reverse current flows in the semiconductor device shown in FIG. 8.

FIG. 10 is a circuit diagram showing a configuration example of the main part of a modified semiconductor device in the second embodiment.

FIG. 11 is a circuit diagram showing a configuration example of the main part of the semiconductor device according to a third embodiment.

FIG. 12 is a timing chart showing an operation example when there is no over-temperature state and reverse current flows in the semiconductor device shown in FIG. 11.

FIG. 13A is a schematic diagram showing a layout configuration example of the semiconductor device in FIG. 11.

FIG. 13B is a schematic diagram showing a different layout configuration example from FIG. 13A.

FIG. 13C is a schematic diagram showing a different layout configuration example from FIG. 13A.

FIG. 13D is a schematic diagram showing a different layout configuration example from FIG. 13A.

FIG. 14 is a cross-sectional view showing a configuration example between B-B' in FIG. 13A.

FIG. 15 is a circuit diagram showing a configuration example of the semiconductor device as a comparative example.

FIG. 16 is a timing chart showing an operation example when there is no over-temperature state and reverse current flows in the semiconductor device shown in FIG. 15.

### DETAILED DESCRIPTION

In the following embodiments, for convenience, when necessary, the description may be divided into multiple sections or embodiments, but unless specifically stated otherwise, they are not unrelated to each other, and one is related to the other as a part or all of a modified example, detail, supplementary explanation, etc. Also, in the following embodiments, when referring to the number of elements, etc. (including the number, numerical values, quantities, ranges, etc.), unless specifically stated otherwise and unless it is clearly limited to a specific number in principle, it is not limited to that specific number and may be more or less than the specific number.

Furthermore, in the following embodiments, the constituent elements (including element steps, etc.) are not necessarily essential unless specifically stated otherwise and unless it is clearly considered essential in principle. Similarly, in the following embodiments, when referring to the shapes, positional relationships, etc. of components, unless specifically stated otherwise and unless it is clearly considered otherwise in principle, it is assumed to include those substantially approximate or similar to those shapes, etc. The same applies to the above numerical values and ranges.

In the following embodiments, a p-channel type MOSFET (Metal Oxide Semiconductor Field Effect Transistor) and an n-channel type MOSFET are referred to as pMOS transistors and nMOS transistors, respectively. Hereinafter, embodiments of the present invention will be described in detail with reference to the drawings. In all the drawings for explaining the embodiments, members having the same functions are denoted by the same reference numerals, and repetitive descriptions thereof are omitted.

### First Embodiment

### Circuit Configuration of Semiconductor Device

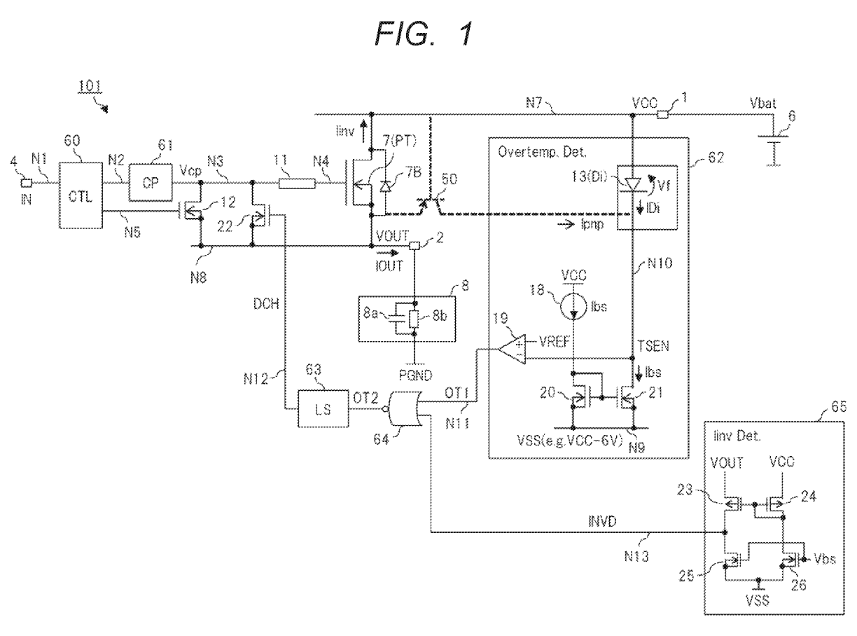

FIG. 1 is a circuit diagram showing a configuration example of a main part of a semiconductor device 101 according to a first embodiment. The semiconductor device 101 shown in FIG. 1 comprises a power supply terminal 1, a power output terminal 2, a control input terminal 4, a power transistor (PT) 7, and various control circuits for controlling the power transistor (PT) 7. The various control circuits comprise an on-off control circuit 60, a charge pump circuit 61, control switches 12, 22, an over-temperature detection circuit 62, a level shift circuit 63, a mask circuit 64, and a reverse current detection circuit 65.

The power supply terminal 1 inputs a battery voltage Vbat, such as 12V, from an external battery 6. As a result, the power supply terminal 1, i.e., a power supply node N7, is supplied with a power supply voltage VCC. A load 8 is coupled to the power output terminal 2. The load 8 is, for example, a capacitive or inductive load and has a parallel-coupled load 8a and resistive load 8b. One end of the load 8 is supplied with a ground power supply voltage PGND. Also, the power output terminal 2 generates an output voltage VOUT and an output current IOUT.

The power transistor (PT) 7 is also an output transistor coupled between the power supply terminal 1 and the power output terminal 2. The power transistor (PT) 7 supplies power to the load 8 coupled to the power output terminal 2 when controlled to be on. In this example, the power transistor (PT) 7 is an nMOS transistor. Source and drain of the power transistor (PT) 7 are coupled to the power output terminal 2 and the power supply terminal 1, respectively. The power transistor (PT) also has a body diode 7B with a commonly coupled source and back gate as an anode and a drain as a cathode.

The control input terminal 4 inputs an on-off control signal IN from outside. The on-off control circuit 60 exclusively controls the charge pump circuit 61 and a control switch 12 in response to the on-off control signal IN. The control switch 12 is, for example, an nMOS transistor. The control switch 12 short-circuits an output node N3 of the charge pump circuit 61 and the power output terminal 2, i.e., a power output node N8, when controlled to be on.

For example, when the on-off control signal IN is at an on level, the on-off control circuit 60 activates the charge pump circuit 61. As a result, the charge pump circuit 61 generates a boosted voltage Vcp that is higher than the power supply voltage VCC. The boosted voltage Vcp is applied to the gate node of the power transistor (PT) 7 through a control resistor 11. On the other hand, when the on-off control signal IN is at an off level, the on-off control circuit 60 controls the control switch 12 to turn on. As a result, the power transistor (PT) 7 is turned off by controlling a gate-source path to be short-circuited through the control resistor 11 and the control switch 12.

The over-temperature detection circuit 62 protects the power transistor (PT) 7 from overheating, for example, when an overload short-circuit occurs. The over-temperature detection circuit 62 comprises a temperature sensing diode (Di) 13, a bias circuit, and a comparator 19. The temperature sensing diode (Di) 13 is arranged adjacent to the power transistor (PT) 7. This allows the temperature sensing diode (Di) 13 to generate a forward voltage Vf that reflects the temperature of the power transistor (PT) 7. The over-temperature detection circuit 62 schematically detects overheating of the power transistor (PT) 7 by comparing the magnitude of the forward voltage Vf with a threshold voltage. The over-temperature detection circuit 62 asserts an over-temperature detection signal OT1 when overheating is detected.

In detail, the bias circuit of the over-temperature detection circuit 62 comprises nMOS transistors 20 and 21, which form a current mirror circuit, and a bias current source 18 that supplies a bias current Ibs to the mirror source nMOS transistor 20. The temperature sensing diode (Di) 13 is provided in series with the bias circuit and is coupled in series with the mirror destination nMOS transistor 21 between the power supply node N7 and an internal power supply node N9.

Thus, the bias circuit supplies the bias current Ibs to the temperature sensing diode (Di) 13. That is, a diode current IDi equal to the bias current Ibs normally flows through the temperature sensing diode (Di) 13. Note that an internal power supply voltage VSS, generated by a circuit not shown, is supplied to the internal power supply node N9. The internal power supply voltage VSS is, for example, approximately 6V lower than the power supply voltage VCC of the power supply node N7.

The comparator 19 inputs a temperature sensing voltage TSEN, which occurs at a connection node N10 between the temperature sensing diode (Di) 13 and the bias circuit, to one of two inputs of the comparator 19. The comparator 19 inputs a reference voltage VREF, which is generated with reference to the power supply node N7 and represents the threshold voltage for overheating, and thus the threshold temperature for overheating, to the other of its two inputs. The temperature sensing voltage TSEN increases as the temperature rises and decreases as the temperature falls, based on a negative temperature characteristic of the forward voltage Vf.

Therefore, when a junction temperature of the power transistor (PT) 7 is lower than the threshold temperature, i.e., in a non-overheating state, TSEN becomes lower than VREF "TSEN<VREF". Accordingly, the comparator 19 outputs the over-temperature detection signal OT1 with a negated level, here an "H" level. On the other hand, when the junction temperature of the power transistor (PT) 7 is higher than the threshold temperature, i.e., in an overheating state, TSEN becomes higher than VREF "TSEN>VREF", and the comparator 19 outputs the over-temperature detection signal OT1 with an asserted level, here an "L" level.

The over-temperature detection signal OT1 is output to the control switch 22 after logical inversion by the mask circuit 64 and level shifting by the level shift circuit 63. The control switch 22 is, for example, an nMOS transistor, and is coupled in parallel with the control switch 12. The control switch 22 controls the power transistor (PT) 7 to be off by shorting the output node N3 of the charge pump circuit 61 to the power output node N8 when the control switch 22 is controlled to turn on.

The level shift circuit 63 shifts a signal from the mask circuit 64, which is based on the internal power supply voltage VSS, to a signal based on the output voltage VOUT. The control switch 22, i.e., the nMOS transistor, inputs the signal, which is level-shifted by the level shift circuit 63, to between a gate and a source of the nMOS transistor as a discharge control voltage DCH. Note that details of the mask circuit 64 and the reverse current detection circuit 65 will be described later.

### Device Configuration of the Semiconductor Device

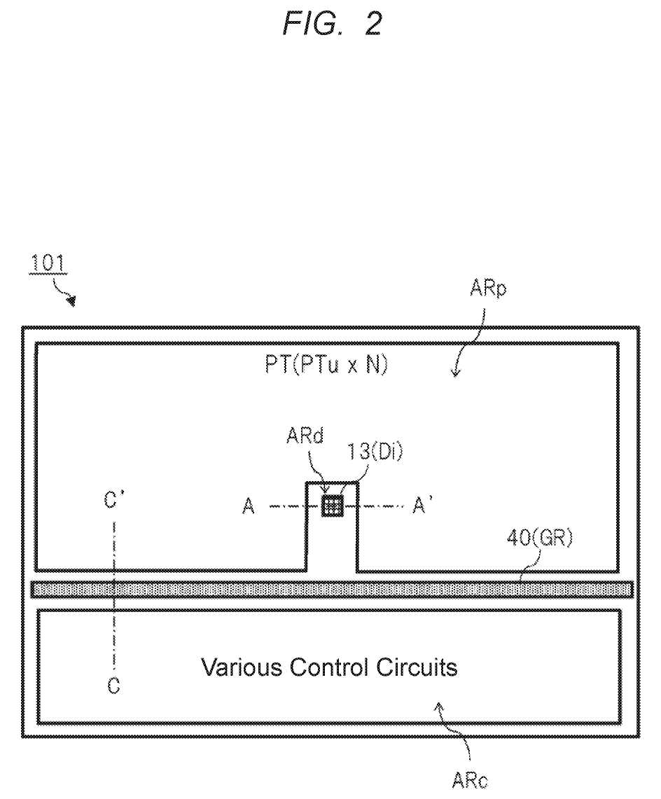

FIG. 2 is a schematic diagram showing an example of a layout of the semiconductor device 101 in FIG. 1. The various control circuits are circuits for controlling the power transistor (PT) 7, as described in FIG. 1. Also, a guard ring (GR) 40 is provided between a formation region ARp and a formation region ARc.

The power transistor (PT) 7, specifically the output transistor, comprises multiple unit output transistors PTu coupled in parallel. Additionally, the temperature sensing diode (Di) 13 is formed in a rectangular region ARd provided inside the formation region ARp, adjacent to the unit output transistors PTu. Consequently, two or more sides of the rectangular region ARd are adjacent to one or more unit output transistors PTu. In this example, the temperature sensing diode (Di) 13 is formed in the rectangular region ARd located approximately at a center of the formation region Arp to detect higher temperatures within the formation region ARp. As a result, three sides of the rectangular region ARd are adjacent to one or more unit output transistors PTu.

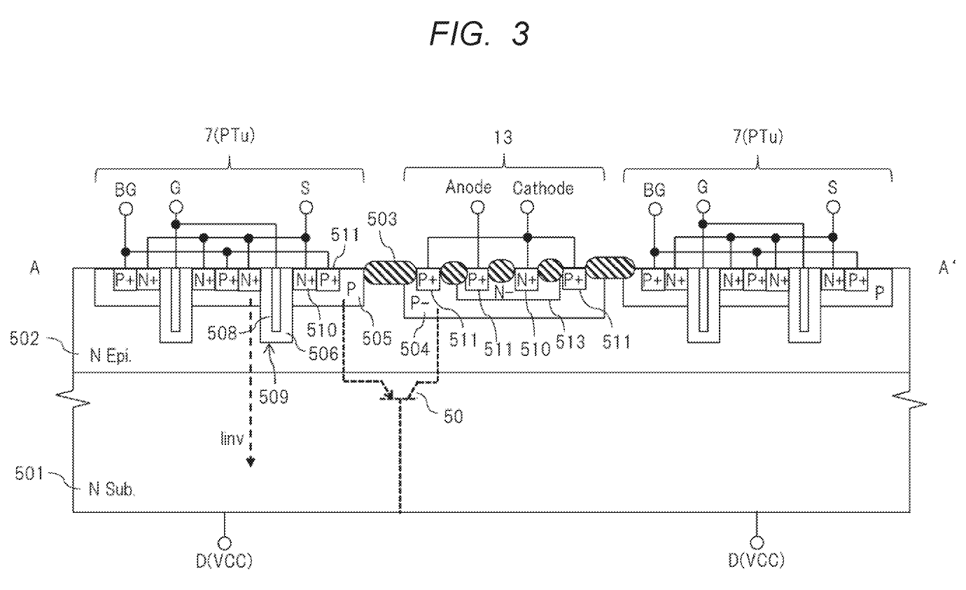

FIG. 3 is a cross-sectional view showing an example of a configuration between A-A' in FIG. 2. In FIG. 3, the unit output transistors PTu constituting the power transistor (PT) 7 and the temperature sensing diode (Di) 13 are illustrated. In FIG. 3, an N-type epitaxial layer 502 is formed on an N-type semiconductor substrate 501. The unit output transistors PTu and the temperature sensing diode (Di) 13 are formed using diffusion layers and the like arranged on the surface of the epitaxial layer 502. Furthermore, the unit output transistors PTu and the temperature sensing diode (Di) 13 are arranged adjacent to each other and are separated by a thick oxide film 503 (LOCOS).

The unit output transistor PTu comprises a vertical nMOS transistor with a back surface of the semiconductor substrate 501 serving as a drain. Specifically, in the unit output transistor PTu, a Pbase diffusion layer 505, which serves as a back gate (BG), is formed on the surface of the epitaxial layer 502. Within the Pbase diffusion layer 505, an N+ type source (S) diffusion layer 510 and a P+ type power supply diffusion layer 511 for feeding the back gate (BG) are formed. The epitaxial layer 502 and the semiconductor substrate 501 serve as a drain (D). The power supply voltage VCC is supplied to the back surface of the semiconductor substrate 501, which is the drain (D).

Additionally, a trench 509 extending in a depth direction is formed in the epitaxial layer 502. Within the trench 509, a thin gate oxide film 506 and a polysilicon 508, which serves as a gate (G), are embedded. The source (S) diffusion layer 510 is formed at a position in contact with a sidewall of the trench 509. When a predetermined voltage is applied between the gate (G) and the source (S), a channel is formed at a location on the sidewall of the trench 509 in the Pbase diffusion layer 505. As a result, a drive current flows from the back surface of the semiconductor substrate 501 towards the source (S) diffusion layer 510.

On the other hand, in the temperature sensing diode (Di) 13, a P- type deep diffusion layer 504 is formed on the surface of the epitaxial layer 502. Within the P- type diffusion layer 504, the P+ type diffusion layer 511 and an N- type shallow diffusion layer 513 are formed. Within the N- type diffusion layer 513, the N+ type diffusion layer 510 and a P+ type diffusion layer 511 are formed. Here, the P+ type diffusion layer 511 formed within the P- type diffusion layer 504 and the N+ type diffusion layer 510 formed within the N- type diffusion layer 513 are shorted by an upper metal layer. This shorted diffusion layer serves as a cathode of the temperature sensing diode (Di) 13. Meanwhile, the P+ type diffusion layer 511 formed within the N- type diffusion layer 513 serves as an anode of the temperature sensing diode (Di) 13.

Here, as shown in FIG. 3, when the unit output transistor PTu and the temperature sensing diode (Di) 13 are arranged adjacent to each other, a parasitic bipolar transistor 50 of the PNP type is formed between them. The parasitic bipolar transistor 50 operates with the back gate (BG) of the unit output transistor PTu as an emitter and the drain (D) as a base. Additionally, the parasitic bipolar transistor 50 operates with a part of the cathode of the temperature sensing diode (Di) 13, specifically the P+ type diffusion layer 511 within the P- type diffusion layer 504, as a collector.

Assuming the formation of such a parasitic bipolar transistor 50, in the unit output transistor PTu, consider a case in which a reverse current Iinv flows from the source (S) diffusion layer 510 towards the back surface of the semiconductor substrate 501, contrary to the drive current. More specifically, in FIG. 1, when the power transistor (PT) 7 is in the off state and the output voltage VOUT becomes, for example, 0.6V or higher than the power supply voltage VCC, a case is considered where the reverse current Iinv flows through the body diode 7B.

In this case, the parasitic bipolar transistor 50 turns on because a forward bias of 0.6V or more is applied between the base and emitter. As a result, a parasitic current Ipnp flows into the cathode of the temperature sensing diode (Di) 13 due to the parasitic bipolar transistor 50. Consequently, the diode current IDi decreases by the increase in the parasitic current Ipnp, causing the temperature sensing voltage TSEN to rise. For example, even if the junction temperature of the power transistor (PT) 7 is not in an over-temperature state, if the temperature sensing voltage TSEN rises above the reference voltage VREF, the comparator 19 erroneously asserts the over-temperature detection signal OT1.

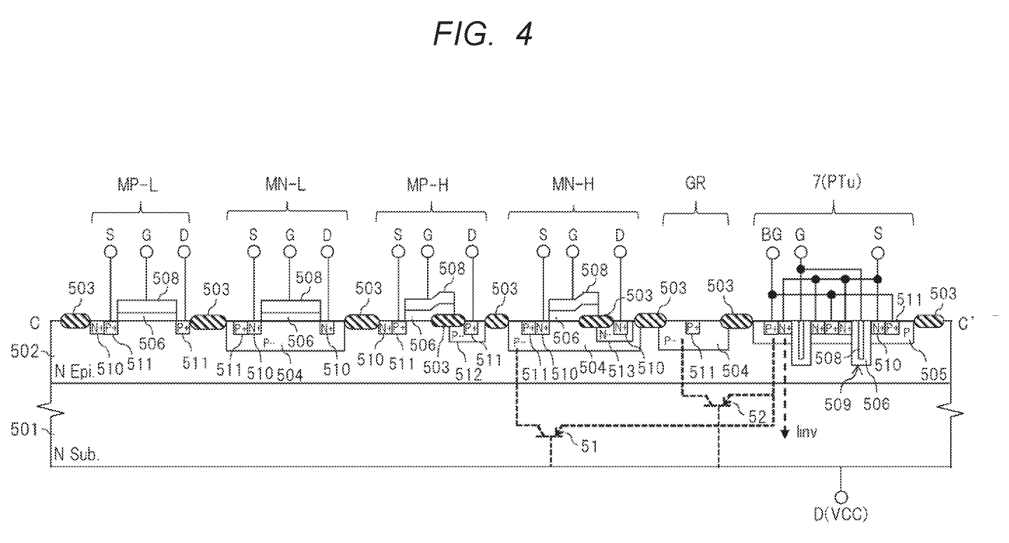

FIG. 4 is a cross-sectional view showing an example of the configuration between C-C' in FIG. 2. In FIG. 4, in addition to the unit output transistor PTu as in FIG. 3, a low-voltage specification pMOS transistor MP-L and nMOS transistor MN-L, a high-voltage specification pMOS transistor MP-H and nMOS transistor MN-H, and the guard ring GR are shown. The pMOS transistors MP-L, MP-H and nMOS transistors MN-L, MN-H are included in various control circuits. The high-voltage specification pMOS transistor MP-H and nMOS transistor MN-H have a breakdown voltage of, for example, about 40V. On the other hand, the low-voltage specification pMOS transistor MP-L and nMOS transistor MN-L have a breakdown voltage of, for example, about 6V.

In the low-voltage specification pMOS transistor MP-L, the P+ type source (S) diffusion layer 511 and the drain (D) diffusion layer 511, and the N+ type power supply diffusion layer 510 for the back gate are formed on the surface of the epitaxial layer 502. On the epitaxial layer 502 located between the source (S) diffusion layer 511 and the drain (D) diffusion layer 511, the polysilicon 508, which serves as the gate (G), is formed via a thin gate oxide film 506.

In the low-voltage specification nMOS transistor MN-L, the P- type deep diffusion layer 504, i.e., a p-well, is formed from the surface of the epitaxial layer 502. Within the P- type diffusion layer 504, the N+ type source (S) diffusion layer 510 and the drain (D) diffusion layer 510, and the P+ type power supply diffusion layer 511 for the back gate are formed. On the epitaxial layer 502 located between the source (S) diffusion layer 510 and the drain (D) diffusion layer 510, the polysilicon 508, which serves as the gate (G), is formed via the thin gate oxide film 506.

In the high-voltage specification pMOS transistor MP-H, the P+ type source (S) diffusion layer 511 and the N+ type power supply diffusion layer 510 for the back gate are formed on the surface of the epitaxial layer 502. On the other hand, on the drain (D) side, the P- type deep diffusion layer 512 is formed from the surface of the epitaxial layer 502. Within the P- type diffusion layer 512, the P+ type drain (D) diffusion layer 511 is formed.

Additionally, on the epitaxial layer 502 is located between the source (S) diffusion layer 511 and the drain (D) diffusion layer 511, the polysilicon 508, which serves as the gate (G), is formed via the thin gate oxide film 506. However, unlike the low-voltage specification pMOS transistor MP-L, the gate oxide film 506 and the polysilicon 508 near the drain (D) are overlaid on the thick oxide film 503 to achieve high breakdown voltage.

In the high-voltage specification nMOS transistor MN-H, the P- type deep diffusion layer 504, i.e., a p-well, is formed from the surface of the epitaxial layer 502. Within the P- type diffusion layer 504, an N+ type source (S) diffusion layer 510 and the P+ type power supply diffusion layer 511 for the back gate are formed. On the other hand, on the drain (D) side, the N- type deep diffusion layer 513 is formed from the surface of the epitaxial layer 502. Within the N- type diffusion layer 513, the N+ type drain (D) diffusion layer 510 is formed.

Additionally, on the epitaxial layer 502 is located between the source (S) diffusion layer 510 and the drain (D) diffusion layer 510, the polysilicon 508, which serves as the gate (G), is formed via the thin gate oxide film 506. However, unlike the low-voltage specification nMOS transistor MN-L, the gate oxide film 506 and the polysilicon 508 near the drain (D) are overlaid on the thick oxide film 503 to achieve high breakdown voltage.

In the guard ring GR, the P-type deep diffusion layer 504, i.e., a p-well, is formed from the surface of the epitaxial layer 502. Within the P-type diffusion layer 504, the P+ type power supply diffusion layer 511 is formed. For example, the ground power supply voltage is applied to the P+ type power supply diffusion layer 511.

As shown in FIG. 4, for example, a parasitic PNP bipolar transistor 51 can be formed between the unit output transistor PTu and the nMOS transistor MN-H located near the unit output transistor PTu. Furthermore, by providing the guard ring GR, the parasitic PNP bipolar transistor 52 can also be formed between the unit output transistor PTu and the guard ring GR. A current path on the side of the parasitic bipolar transistor 52 is of low impedance. As a result, much of the parasitic current that may flow into the parasitic bipolar transistor 51 can be diverted to the guard ring GR.

For example, in FIG. 3, if the guard ring GR as shown in FIG. 4 is provided between the unit output transistor PTu and the temperature sensing diode (Di) 13, the parasitic current Ipnp flowing into the cathode of the temperature sensing diode (Di) 13 can be reduced. However, providing the guard ring GR may prevent an accurate detection of the temperature of the power transistor (PT) 7. Therefore, to eliminate an influence of the parasitic current Ipnp without providing the guard ring GR, the mask circuit 64 and the reverse current detection circuit 65 as shown in FIG. 1 are provided.

### Details of the mask circuit and the reverse current detection circuit

In FIG. 1, the reverse current detection circuit 65 detects the occurrence of the reverse current Iinv from the power output terminal 2 to the power supply terminal 1 and asserts a reverse current detection signal INVD during the period when the reverse current Iinv is occurring. Specifically, the reverse current detection circuit 65 includes pMOS transistors 23, 24 and nMOS transistors 25, 26, which form a source-input type differential amplifier circuit.

A gate of the pMOS transistor 24 is coupled to its drain and also to a gate of the pMOS transistor 23. The pMOS transistors 23 and 24 respectively input the output voltage VOUT and the power supply voltage VCC to their sources. The nMOS transistors 25, 26 are supplied with an internal power supply voltage VSS to their sources. The nMOS transistors 25, 26 respectively supply a common bias current based on the bias voltage Vbs from their drains to the pMOS transistors 23, 24.

With this configuration, the reverse current detection circuit 65 functions as a comparator that detects a magnitude relationship between the output voltage VOUT and the power supply voltage VCC, and thus detects a presence or absence of the reverse current Iinv. When the reverse current Iinv is flowing, "VOUT>VCC," so a gate-source voltage of the pMOS transistor 23 becomes larger than that of the pMOS transistor 24. As a result, the reverse current detection circuit 65 outputs the asserted level, here the "H" level, reverse current detection signal INVD to an output node N13. On the other hand, when the reverse current Iinv is not flowing, the reverse current detection circuit 65 outputs the negated level, here the "L" level, reverse current detection signal INVD.

The mask circuit 64 inputs the reverse current detection signal INVD and the over-temperature detection signal (first over-temperature detection signal) OT1 from the over-temperature detection circuit 62. Then, by performing a predetermined logical operation, the mask circuit 64 generates an over-temperature detection signal (second over-temperature detection signal) OT2 that is fixed at the negated level during the assert period of the reverse current detection signal INVD, i.e., fixed in a non-over-temperature state during the period when the reverse current Iinv is flowing.

In this example, the mask circuit 64 is configured as a NOR gate. In this case, during the assert period of the reverse current detection signal INVD, here the "H" level period, the mask circuit 64 outputs an over-temperature detection signal OT2 fixed at the negated level, here the "L" level. On the other hand, during a negated period of the reverse current detection signal INVD, here the "L" level period, the mask circuit 64 inverts and outputs the input the over-temperature detection signal OT1. Therefore, in the over-temperature detection signal OT2, the asserted level and the negated level are opposite to those of the over-temperature detection signal OT1, being the "H" level and the "L" level, respectively.

The level shift circuit 63 level-shifts the over-temperature detection signal OT2 and outputs it as the discharge control voltage DCH to the control switch 22. As a result, the control switch 22 is turned off based on the reverse current detection signal INVD from the reverse current detection circuit 65 during the period when the reverse current Iinv is flowing. On the other hand, during the period when the reverse current Iinv is not flowing, the control switch 22 is controlled to turn on and off based on the over-temperature detection signal OT1 from the over-temperature detection circuit 62. For example, when an over-temperature is detected, the control switch 22 is turned on based on the asserted level over-temperature detection signal OT1. This interrupts the drive current flowing to the power transistor (PT) 7, i.e., the output current IOUT to the load 8.

### Operation of Semiconductor Device

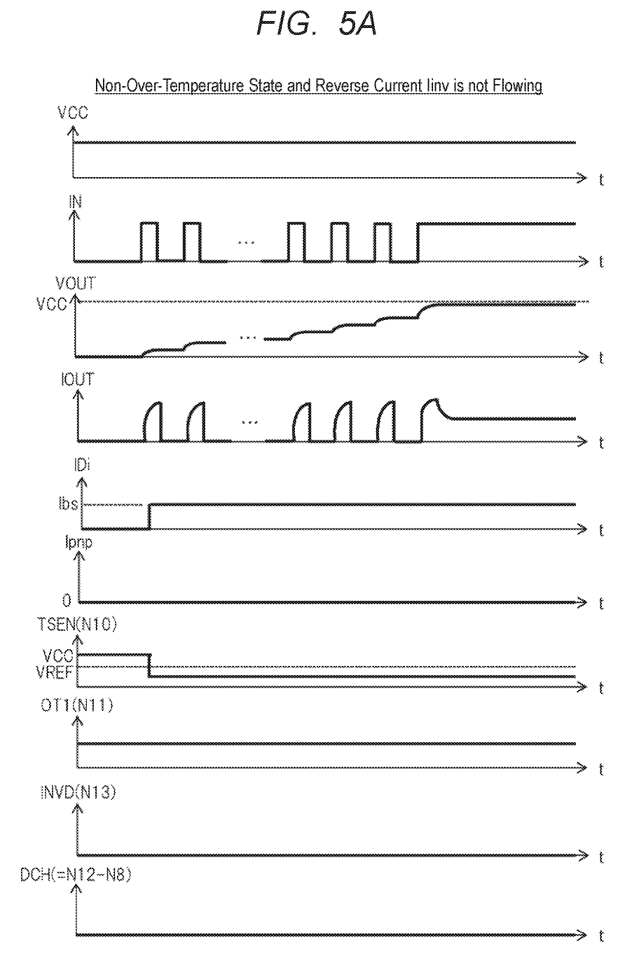

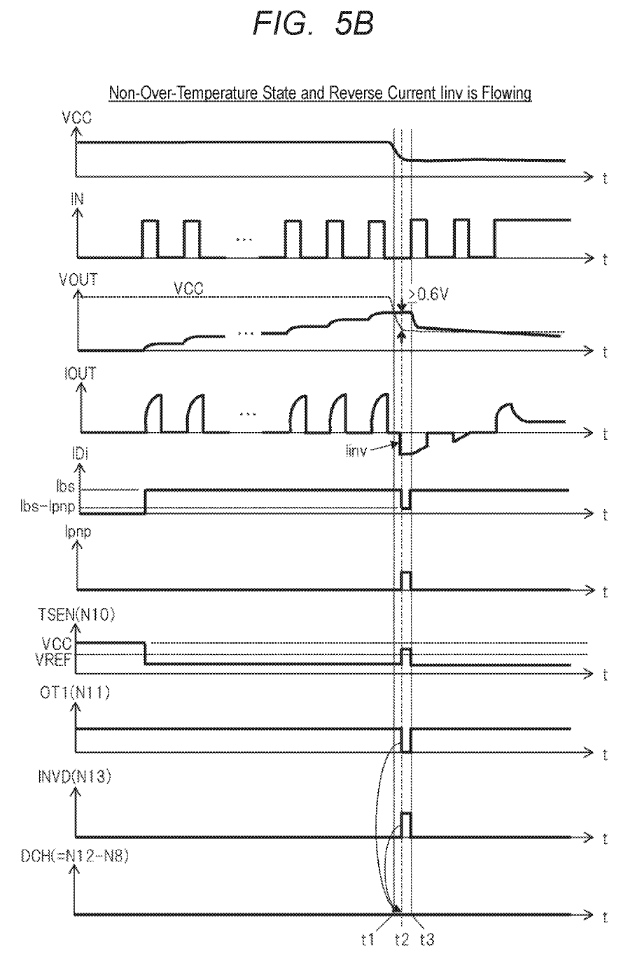

FIG. 5A is a timing chart showing an example of operation when the semiconductor device 101 shown in FIG. 1 is in the non-over-temperature state and the reverse current Iinv is not flowing. When supplying power to the load 8 as shown in FIG. 1, an inrush current flows when charging the load 8a by turning on the power transistor (PT) 7. To suppress the inrush current, as shown in FIG. 5A, the operation periodically switching on and off using the on-off control signal IN is performed. This allows the semiconductor device 101 to charge the load 8a step by step.

When the on-off control signal IN is at the "H" level, the charge pump circuit 61 performs a boosting operation, while the control switch 12 turns off. As a result, the output node N3 of the charge pump circuit 61 and a gate node N4 of the power transistor (PT) 7 are boosted to a boosted voltage Vcp higher than the power supply node N7. Consequently, the power transistor (PT) 7 turns on and charges the load 8a.

On the other hand, when the on-off control signal IN is at the "L" level, the control switch 12 turns on, while the charge pump circuit 61 stops the boosting operation. As a result, a voltage of the gate node N4 of the power transistor (PT) 7 is pulled down to a voltage of the power output node N8, which is a source node. Consequently, the power transistor (PT) 7 turns off, stopping the charging of the load 8a. By repeating these steps, the load 8a is charged step by step while limiting a maximum value of the inrush current.

Here, in the non-over-temperature state, in the over-temperature detection circuit 62, the temperature sensing voltage TSEN generated at the connection node N10 is lower than the reference voltage VREF, so the comparator 19 outputs the negated level, here the "H" level, over-temperature detection signal OT1. Also, in the reverse current detection circuit 65, since "VOUT<VCC," the pMOS transistor 23 turns off after differential amplification operation. As a result, the reverse current detection circuit 65 outputs the negated level, here the "L" level, reverse current detection signal INVD to the output node N13.

The mask circuit 64 inputs the negated level reverse current detection signal INVD and the negated level over-temperature detection signal OT1 and outputs the negated level, here the "L" level, over-temperature detection signal OT2. In response, the level shift circuit 63 outputs the "L" level discharge control voltage DCH to node N12, based on the voltage of the power output node N8. As a result, the control switch 22 remains off.

Although not shown, in the over-temperature state, the temperature sensing voltage TSEN is higher than the reference voltage VREF, so the comparator 19 outputs the asserted level, here the "L" level, over-temperature detection signal OT1. Also, as in the non-over-temperature state described above, the reverse current detection circuit 65 outputs the "L" level reverse current detection signal INVD. The mask circuit 64 outputs the asserted level, here the "H" level, over-temperature detection signal OT2 in response to the asserted level over-temperature detection signal OT1. Then, the control switch 22 turns on based on the "H" level discharge control voltage DCH from the level shift circuit 63. This protects the power transistor (PT) 7 by turning it off.

FIG. 5B is a timing chart showing an example of operation when the semiconductor device 101 shown in FIG. 1 is in the non-over-temperature state and the reverse current Iinv is flowing. In FIG. 5B, unlike FIG. 5A, at time t1, a drop in the power supply voltage VCC occurs during the off period of the power transistor (PT) 7, resulting in the state "VOUT>VCC". When the power transistor (PT) 7 is off, no channel is formed, so the reverse current Iinv can flow through the body diode 7B. Specifically, the reverse current Iinv begins to flow from time t2, for example, when "VOUT-VCC" exceeds the forward voltage of the body diode 7B, approximately 0.6V.

When the reverse current Iinv begins to flow, the parasitic bipolar transistor 50 between the power transistor (PT) 7 and the temperature detection diode (Di) 13 is turned on as a base-emitter junction becomes forward-biased. As a result, the parasitic current Ipnp flows into the cathode of the temperature detection diode (Di) 13. The diode current IDi is equal to the bias current Ibs when the parasitic current Ipnp is not flowing but becomes "Ibs-Ipnp" when the parasitic current Ipnp flows. The temperature detection voltage TSEN generated at the connection node N10 is determined based on a magnitude of this "Ibs-Ipnp."

Specifically, as a magnitude of the parasitic current Ipnp approaches a magnitude of the bias current Ibs, the diode current IDi decreases, and a value of the temperature detection voltage TSEN approaches a value of the power supply voltage VCC. Particularly, when the parasitic current Ipnp becomes larger than the bias current Ibs, the diode current IDi becomes zero, causing the temperature sensing voltage TSEN to rise significantly through the parasitic bipolar transistor 50. Due to an influence of such parasitic current Ipnp, when the temperature sensing voltage TSEN becomes higher than the reference voltage VREF of the comparator 19, the over-temperature detection signal OT1 is erroneously asserted to the "L" level, despite not being in the over-temperature state.

In this example, the over-temperature detection signal OT1 is at the asserted level from time t2 until the time t3 when the power transistor (PT) 7 is turned on. When the power transistor (PT) 7 is turned on, the voltage difference between the output voltage VOUT and the power supply voltage VCC approaches zero through the power transistor (PT) 7 with on state.

In such an operation, as described above, by providing the reverse current detection circuit 65 and the mask circuit 64, it is possible to control so that the erroneous over-temperature detection signal OT1 from the over-temperature detection circuit 62 is not transmitted to the control switch 22. Specifically, when the power supply voltage VCC becomes 0.6V or more lower than the output voltage VOUT, the reverse current detection circuit 65 outputs the asserted level, here the "H" level, reverse current detection signal INVD to the output node N13. In this example, the "H" level reverse current detection signal INVD is output during the period from time t2 to time t3.

The mask circuit 64 masks, or in other words, invalidates the over-temperature detection signal OT1 during the "H" level period of the reverse current detection signal INVD, so that the erroneous over-temperature detection signal OT1 is not transmitted to the control switch 22. That is, the mask circuit 64 outputs an over-temperature detection signal OT2 fixed at the negated level, here the "L" level, regardless of the level of the over-temperature detection signal OT1. Consequently, the control switch 22 inputs the "L" level discharge control voltage DCH and maintains off state.

### Differences from the Semiconductor Device (Comparative Example)

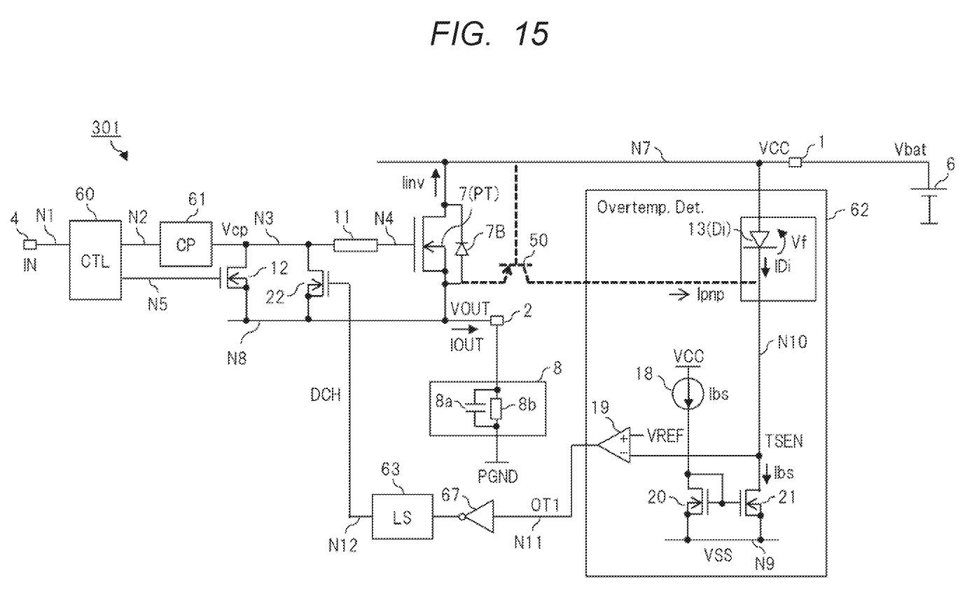

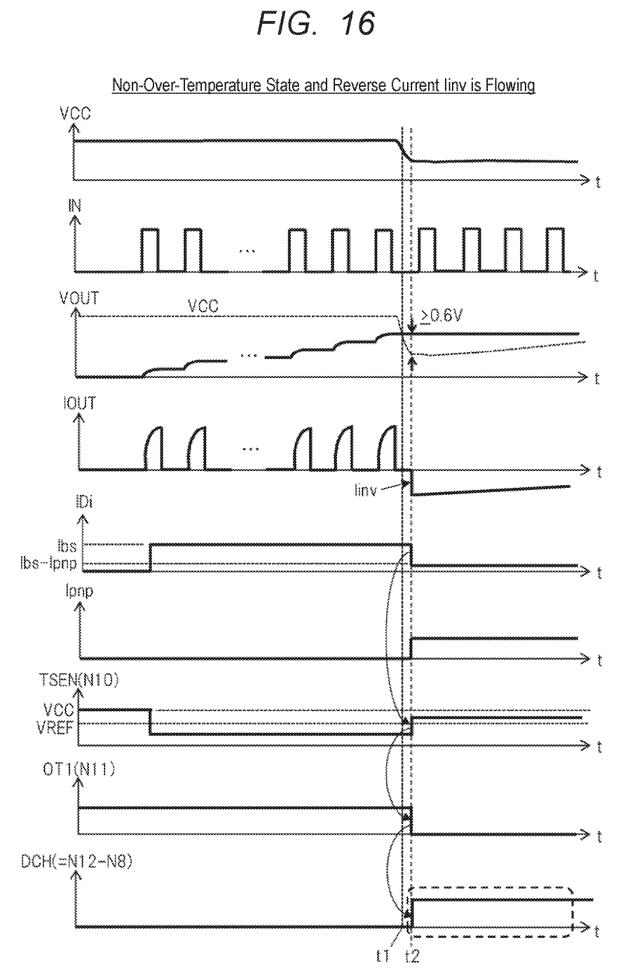

FIG. 15 is a circuit diagram showing a configuration example of a semiconductor device 301 as a comparative example. FIG. 16 is a timing chart showing an operation example when the non-over-temperature state and the reverse current Iinv are flowing in the semiconductor device 301 shown in FIG. 15. The semiconductor device 301 as a comparative example shown in FIG. 15 differs from the configuration example shown in FIG. 1 in the following points. First difference is that the reverse current detection circuit 65 is not provided. Second difference is that the mask circuit 64 is replaced with an inverter circuit 67.

In such a configuration, the over-temperature detection signal OT1 can be erroneously asserted to the "L" level due to an influence of the parasitic current Ipnp accompanying the reverse current Iinv, even though it is in the non-over-temperature state, as described above. Particularly, when the parasitic current Ipnp becomes larger than the bias current Ibs, the over-temperature detection signal OT1 erroneously becomes the "L" level.

The over-temperature detection signal OT1 maintains the "L" level during the period when the reverse current Iinv is flowing, as shown from time t2 onwards in FIG. 16. Consequently, the discharge control voltage DCH maintains the "H" level, so the control switch 22 remains on. As a result, even if the on-off control signal IN switches to the on level, that is, the "H" level, the power transistor (PT) 7 remains off. Consequently, as shown in FIG. 16, the state where the reverse current Iinv is flowing is prolonged, and the power transistor (PT) 7 cannot be turned on until the reverse current Iinv stops flowing.

On the other hand, using the configuration example of FIG. 1, it is possible to detect that the reverse current Iinv is flowing and mask the over-temperature detection signal OT1 during the period when the reverse current Iinv is flowing, allowing the on-off control of the power transistor (PT) 7 based on the on-off control signal IN, even if the reverse current Iinv is flowing. Specifically, as shown from time t2 to time t3 in FIG. 5B, the erroneously asserted over-temperature detection signal OT1 is masked by the mask circuit 64, so the control switch 22 remains off. As a result, when the on-off control signal IN becomes the "H" level at time t3, the power transistor (PT) 7 turns on.

When the power transistor (PT) 7 turns on at time t3, the reverse current Iinv that was flowing through the body diode 7B flows through the power transistor (PT) 7, which has a low channel resistance. As a result, "VOUT-VCC" becomes sufficiently lower than 0.6V, turning off the parasitic bipolar transistor 50. Accordingly, the parasitic current Ipnp becomes zero, and the over-temperature detection signal OT1 returns to the negated level. Concurrently, the output voltage VOUT transitions to become almost equal to the power supply voltage VCC. Additionally, since the charge of the load 8a is discharged through a resistive load 8b, the output voltage VOUT eventually becomes lower than the power supply voltage VCC. As a result, returning to a normal state.

### Application Example to Electronic Control System (ECU)

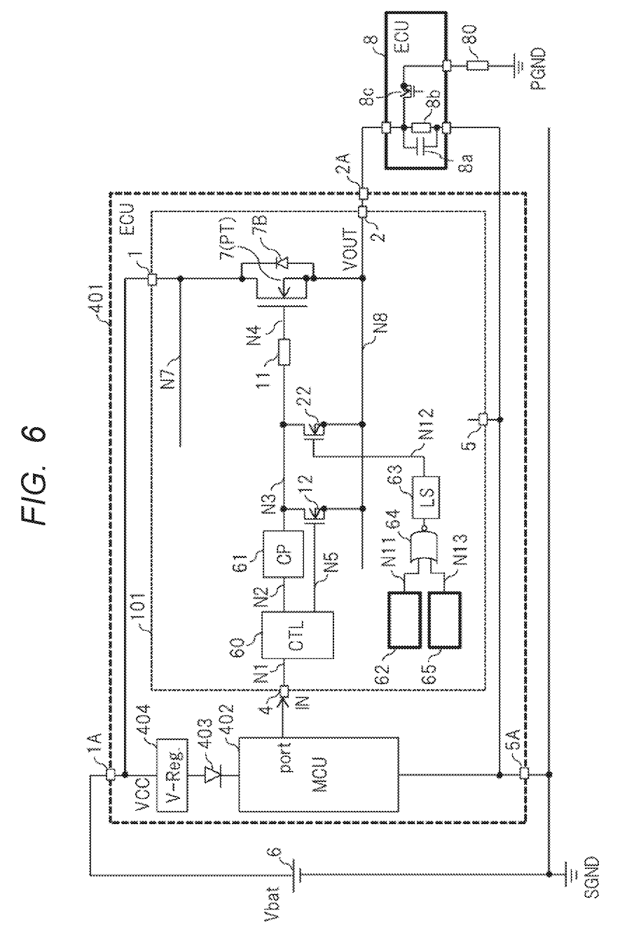

FIG. 6 is a circuit block diagram showing a configuration example of an electronic control system (ECU) 401 to which the semiconductor device 101 shown in FIG. 1 is applied. The electronic control system (ECU) 401 shown in FIG. 6 includes, in addition to the semiconductor device 101 shown in FIG. 1, a power supply regulator 404, a diode 403, and an ECU control device 402, here a microcontroller unit (MCU). The electronic control system (ECU) 401 also has a power supply terminal 1A, a ground power supply terminal 5A, and a power output terminal 2A.

The battery 6 is coupled between the power supply terminal 1A and the ground power supply terminal 5A. The load 8 is coupled to the power output terminal 2A. In this example, the load 8 is another electronic control unit (ECU). The electronic control unit serving as the load 8 is equipped with the load 8a, the resistive load 8b, and a power switch 8c, among others. Another load 80 is coupled between the power output terminal of the electronic control unit, which is also the power output terminal of the power switch 8c, and the ground power supply voltage PGND.

The power supply terminal 1A inputs the battery voltage Vbat. The power supply regulator 404 inputs the power supply voltage VCC obtained at the power supply terminal 1A and generates a low-voltage power supply voltage for the ECU control device 402. The power supply voltage generated is supplied to the ECU control device 402 via diode 403. Additionally, a ground power supply voltage SGND of the battery 6 is supplied to one end of the ECU control device 402 via the ground power supply terminal 5A. The diode 403 serves a protective function of the ECU control device 402, preventing reverse current from flowing into the ECU control device 402 during reverse connection of the battery 6 or the like.

An output port of the ECU control device 402 is coupled to the control input terminal 4 of the semiconductor device 4. The ECU control device 402 outputs an on-off control signal IN to the semiconductor device 101 to instruct the on-off of the power transistor (PT) 7. The Semiconductor device 101 controls the power supply to the load 8 based on the on-off control signal IN from the control input terminal 4. In this case, for example, even if the reverse current Iinv described above occurs due to a drop in the battery voltage Vbat, the power supply to the semiconductor device 101, and consequently to the load 8, can be controlled by the on-off control signal IN from the ECU control device 402.

Note that the power supply voltage VCC from the power supply terminal 1A of the electronic control system (ECU) 401 is supplied to the power supply terminal 1 of the semiconductor device 101. The power output terminal 2 of the semiconductor device 101 is coupled to the power output terminal 2A of the electronic control system (ECU) 401. The semiconductor device 101 also has a ground power supply terminal 5. The ground power supply voltage SGND is supplied to the ground power supply terminal 5 via the ground power supply terminal 5A of the electronic control system (ECU) 401.

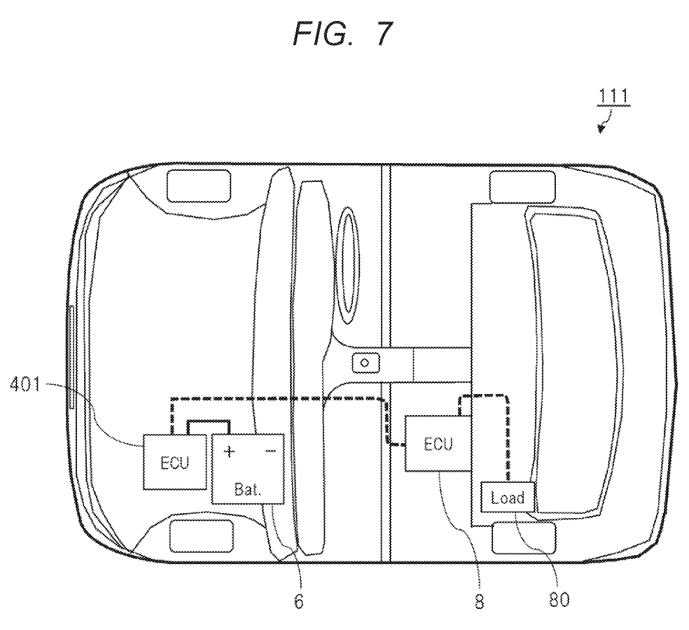

FIG. 7 is a schematic diagram showing a configuration example of a vehicle 111 equipped with the electronic control system (ECU) 401 shown in FIG. 6. The vehicle 111 is, for example, an automobile. As shown in FIG. 7, vehicle 111 is equipped with the battery 6, the electronic control system 401, and the loads 8 and 80. The electronic control system 401 and the load 8, as well as the load 8 and the load 80, are coupled by wire harnesses. Additionally, the ground power supply voltage PGND shown in FIG. 6 is coupled to, for example, a chassis of vehicle 111.

### Main Effects of the First Embodiment

As described above, the semiconductor device 101 according to the first embodiment includes the reverse current detection circuit 65 and the mask circuit 64. This allows for the generation of the correct over-temperature detection signal OT2 even when the reverse current Iinv directed from the load 8 to the power transistor (PT) 7, i.e., the output transistor, occurs. Furthermore, by generating the correct over-temperature detection signal OT2, it is possible to prevent a malfunction of the control switch 22 and avoid situations where the output transistor is fixed in the off state.

### Second Embodiment

### Circuit Configuration and Operation of the Semiconductor Device

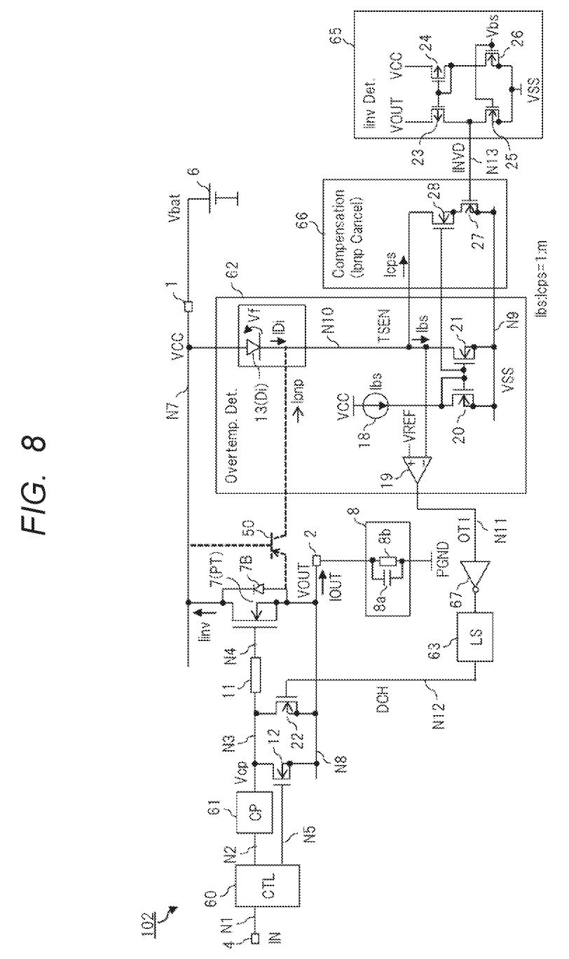

FIG. 8 is a circuit diagram showing a configuration example of a main part of the semiconductor device 102 according to the second embodiment. The method of the first embodiment was to generate a correct over-temperature detection signal OT2 by masking the erroneous over-temperature detection signal OT1 that may occur during the period when the reverse current Iinv is flowing. The method of the second embodiment is to correctly generate the original over-temperature detection signal OT1 itself.

The semiconductor device 102 shown in FIG. 8 differs from the configuration example shown in FIG. 1 in the following points. As the first difference, a compensation circuit 66 is provided. As the second difference, the mask circuit 64 is replaced with the inverter circuit 67 similar to the case in FIG. 15. As the third difference, an output destination of the reverse current detection signal INVD from the reverse current detection circuit 65 is replaced from the mask circuit 64 to the compensation circuit 66.

The compensation circuit 66 generates a compensation current Icps and compensates for a magnitude of the diode current IDi flowing through the temperature detection diode (Di) 13 during the assertion period of the reverse current detection signal INVD using the compensation current Icps. Specifically, the compensation circuit 66 increases the diode current IDi, which is reduced by the parasitic current Ipnp from the parasitic bipolar transistor 50, using the compensation current Icps.

In detail, the compensation circuit 66 includes nMOS transistors 28 and 27. The nMOS transistors 28 and 27 are coupled in series between the cathode of the temperature detection diode (Di) 13, i.e., the connection node N10, and the internal power supply node N9, where the internal power supply voltage VSS is supplied. The nMOS transistor 27 is controlled by the reverse current detection signal INVD and turns on during the assertion period of the reverse current detection signal INVD, i.e., the period during which the reverse current Iinv is flowing.

The gate of the nMOS transistor 28 is commonly coupled with the gate of the nMOS transistor 20 in the over-temperature detection circuit 62. As a result, the nMOS transistor 28 forms a current mirror circuit with the nMOS transistor 20 as a mirror source and the nMOS transistor 28 as a mirror destination during the on period of the nMOS transistor 27. Consequently, the compensation circuit 66 can draw at least a part of the parasitic current Ipnp to the internal power supply voltage VSS during the period when the reverse current Iinv is flowing, and hence when the parasitic current Ipnp is flowing.

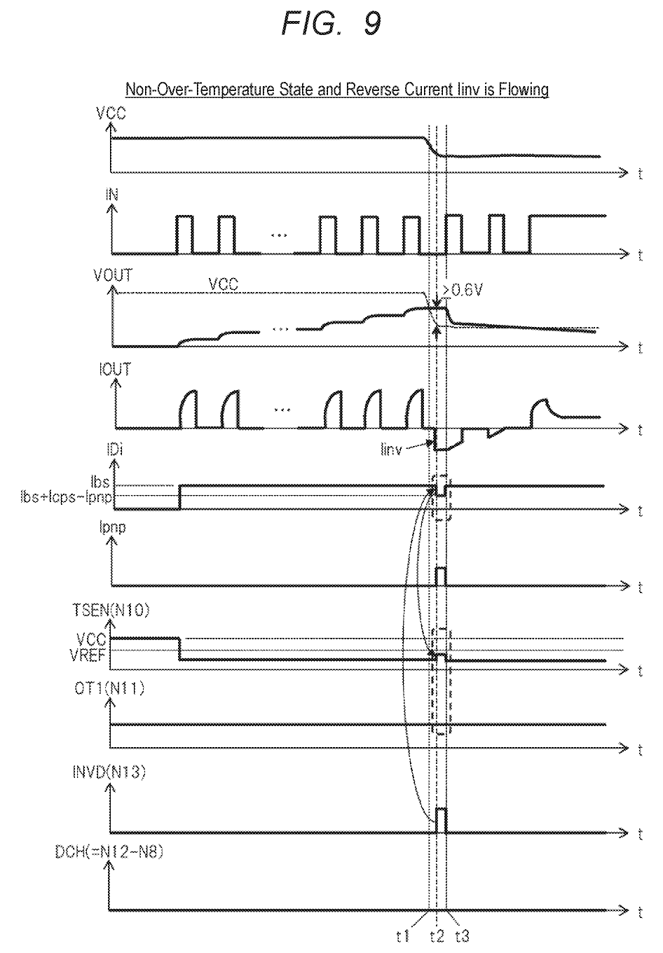

FIG. 9 is a timing chart showing an example of operation in the semiconductor device 102 shown in FIG. 8 when in the non-over-temperature state and the reverse current Iinv is flowing. Here, the explanation focuses on the differences from FIG. 5B. First, as in the case of FIG. 5B, at time t1, a decrease in the power supply voltage VCC occurs during the off period of the power transistor (PT) 7, resulting in the state "VOUT>VCC". At time t2, as "VOUT-VCC" exceeds the forward voltage of the body diode 7B, for example, about 0.6V, the reverse current Iinv begins to flow. Consequently, the parasitic bipolar transistor 50 turns on, causing the parasitic current Ipnp to flow into the cathode of the temperature detection diode (Di) 13.

Meanwhile, when the reverse current Iinv flows, the reverse current detection circuit 65 asserts the reverse current detection signal INVD to the "H" level. As a result, the compensation circuit 66 becomes active as the nMOS transistor 27 turns on. Here, the nMOS transistor 28 in the compensation circuit 66 forms a current mirror circuit with the nMOS transistor 20 in the over-temperature detection circuit 62 and has a transistor size, specifically a gate width, that is m times larger. Consequently, the compensation current Icps, which is m times the bias current Ibs, flows in the compensation circuit 66.

By setting the value of m so that the compensation current Icps becomes approximately equal to the parasitic current Ipnp, the compensation circuit 66 functions as a circuit that bypasses the parasitic current Ipnp. Generally, the magnitude of the bias current Ibs necessary for the normal operation of the temperature detection diode (Di) 13 is, for example, about several microamperes. On the other hand, the parasitic current Ipnp can become significantly larger than several microamperes. Therefore, the value of m can usually be significantly larger than 1.

By appropriately setting the value of m, the bias current Ibs flows through the temperature detection diode (Di) 13 even during the period when the parasitic current Ipnp is flowing. Therefore, the temperature sensing voltage TSEN at the connection node N10 becomes approximately the same as the voltage obtained when the reverse current Iinv and the parasitic current Ipnp are not flowing. As a result, in the non-over-temperature state, the comparator 19 outputs the over-temperature detection signal OT1 at the negated level, in this example, the "H" level, to node N11.

The "H" level over-temperature detection signal OT1 is inverted by the inverter circuit 67 and then transmitted to the control switch 22 as the "L" level discharge control voltage DCH by the level shift circuit 63. Therefore, the control switch 22 remains off. As a result, as mentioned in FIG. 15, even if the reverse current Iinv is flowing, the on-off control of the power transistor (PT) 7 based on the on-off control signal IN is possible.

In FIG. 9, compared to the case in FIG. 5B, the magnitude of the diode current IDi from time t2 to time t3 is different, and accordingly, a magnitude of the temperature sensing voltage TSEN is also different. The magnitude of the temperature sensing voltage TSEN exceeds the reference voltage VREF in FIG. 5B, whereas it does not exceed the reference voltage VREF in FIG. 9. This allows for the correct generation of the over-temperature detection signal OT1 itself. If the aforementioned value of m is ideal, the magnitude of the diode current IDi from time t2 to time t3 will be equal to the bias current Ibs.

### Regarding Modified Examples

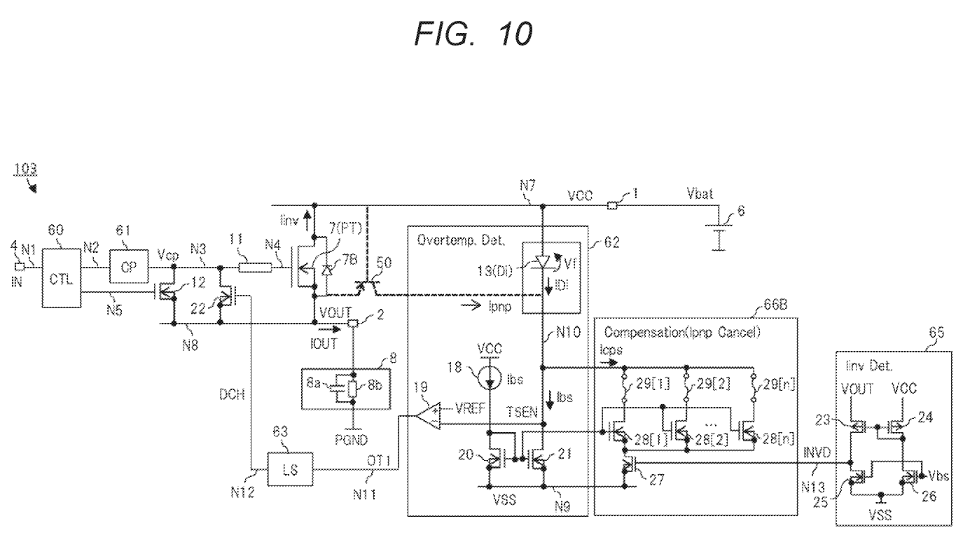

FIG. 10 is a circuit diagram showing a configuration example of a main part of a semiconductor device 103 with a modified configuration of FIG. 8 in the second embodiment. In the configuration example shown in FIG. 8, it is necessary to know a magnitude of the parasitic current Ipnp in advance to set a magnitude of the compensation current Icps. However, the magnitude of the parasitic current Ipnp is considered to vary greatly due to process variation factors. To address this, the semiconductor device 103 shown in FIG. 10 is configured to allow adjustment of the magnitude of the compensation current Icps through testing of the semiconductor device 103.

The semiconductor device 103 shown in FIG. 10 differs from FIG. 8 in the configuration of a compensation circuit 66B. In compensation circuit 66B, the nMOS transistor 28 shown in FIG. 8 is replaced with n nMOS transistors 28[1]-28[n] with fuses 29[1]-29[n] added in series. The fuses 29[1]-29[n] each select whether to connect a drain of the nMOS transistors 28[1]-28[n] to the connection node N10. This allows the compensation circuit 66B to include a variable current source capable of adjusting the magnitude of the compensation current Icps. The nMOS transistors 28[1]-28[n] may be configured, for example, to have different transistor sizes in units of 2N from each other.

Here, during the testing of the semiconductor device 103, the parasitic current Ipnp is first measured. As a specific example, the bias current Ibs is set not to flow into the nMOS transistor 21, and the current value flowing into the connection node N10 is measured with an ammeter while intentionally flowing a reverse current into the power transistor (PT) 7. Then, the fuses 29[1]-29[n] are cut so that the value of the compensation current Icps comes closest to the measured current value. This allows, for example, the diode current IDi from time t2 to time t3 in FIG. 9 to be brought closer to the bias current Ibs.

### Main Effects of the Second Embodiment

As described above, the semiconductor devices 102, 103 according to the second embodiment have the compensation circuit 66 that compensates for the magnitude of the diode current IDi by offsetting the parasitic current Ipnp with the compensation current Icps. This allows for the generation of the correct over-temperature detection signal OT1 even when the reverse current Iinv directed from the load 8 to the output transistor occurs, similar to the case of the first embodiment. Furthermore, by generating the correct over-temperature detection signal OT1, it is possible to prevent the malfunction of the control switch 22 and avoid situations where the output transistor is fixed in the off state.

Moreover, in the method of the second embodiment, unlike the method of the first embodiment, the over-temperature detection signal OT1 is not masked during the period when the reverse current Iinv is flowing, and the over-temperature detection signal OT1, and hence the temperature sensing voltage TSEN, is valid. Therefore, even during this period, over-temperature detection targeting the output transistor can be performed. The more appropriately the compensation current Icps is set, the more accurately the over-temperature detection can be performed.

### Third Embodiment

### Circuit Configuration and Operation of the Semiconductor Device

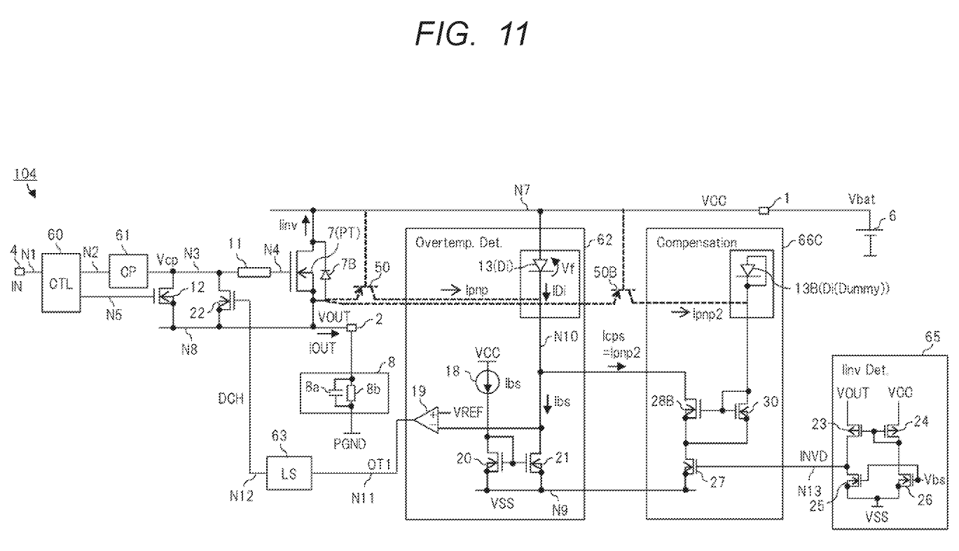

FIG. 11 is a circuit diagram showing a configuration example of a main part of the semiconductor device 104 according to the third embodiment. The method of the third embodiment, like the method of the second embodiment, is to correctly generate the original over-temperature detection signal OT1 itself. However, the method of the third embodiment allows for setting the compensation current Icps with higher precision than the method of the second embodiment.

The semiconductor device 104 shown in FIG. 11 differs from FIG. 8 and FIG. 10 in the configuration of the compensation circuit 66C. The compensation circuit 66C includes a dummy temperature sensing diode 13B. The dummy temperature sensing diode 13B is formed adjacent to the power transistor (PT) 7 on the semiconductor substrate, similar to the temperature sensing diode (Di) 13.

This forms a PNP-type parasitic bipolar transistor (second parasitic bipolar transistor) 50B that turns on due to the reverse current Iinv between the power transistor (PT) 7 and the cathode of the dummy temperature sensing diode 13B. The compensation circuit 66C is configured to set the parasitic current (second parasitic current) Ipnp2 flowing through the parasitic bipolar transistor 50B as the compensation current Icps.

In detail, the compensation circuit 66C includes, in addition to the dummy temperature sensing diode 13B, nMOS transistors 27, 28B, and 30. As in the case of FIG. 8, the nMOS transistor 27 is controlled to turn on and off by the reverse current detection signal INVD. The nMOS transistor 28B, during the period when the nMOS transistor 27 is on, draws the compensation current Icps from the cathode of the temperature sensing diode (Di) 13 to the internal power supply voltage VSS. However, unlike the case of FIG. 8, the nMOS transistor 28B forms a current mirror circuit with the nMOS transistor 30. The cathode of the dummy temperature sensing diode 13B is coupled to the drain of the nMOS transistor 30.

The dummy temperature sensing diode 13B is configured so that no current flows, and in this example, the anode-cathode is short-circuited. That is, the dummy temperature sensing diode 13B is provided only to allow a parasitic current Ipnp2 from the parasitic bipolar transistor 50B to flow into the nMOS transistor 30. When the parasitic current Ipnp2 flows into the parasitic bipolar transistor 50B in response to the reverse current Iinv, the parasitic current Ipnp2 flows as the compensation current Icps into the nMOS transistor 28B, which is the mirror destination, using the nMOS transistor 30 as the mirror source.

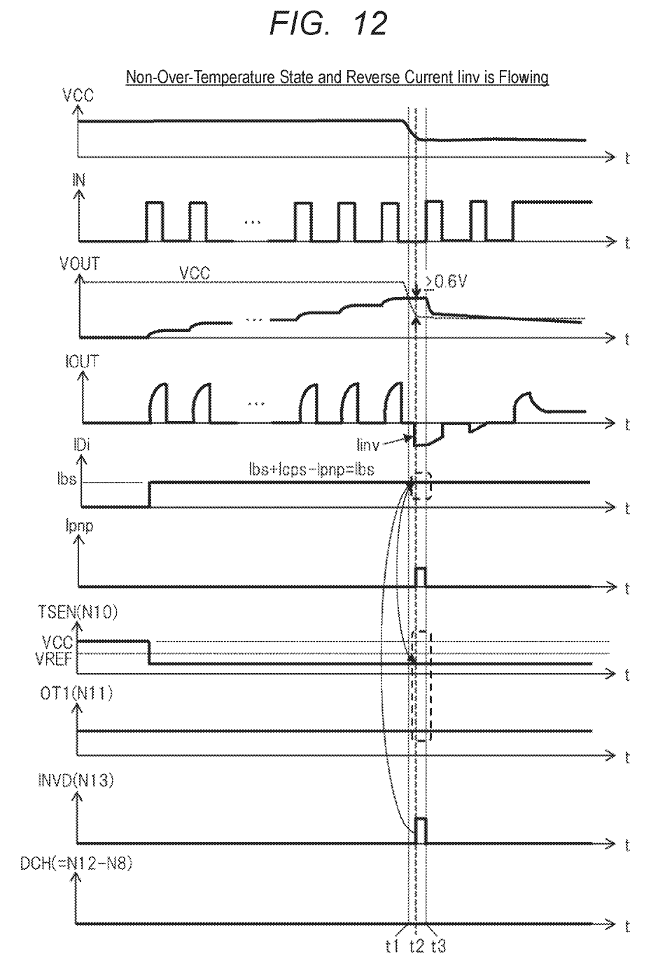

FIG. 12 is a timing chart showing an operation example in the semiconductor device 104 shown in FIG. 11 when in the non-over-temperature state and the reverse current Iinv is flowing. Here, the explanation focuses on the differences from FIG. 9. As in the case of FIG. 9, when the reverse current Iinv flows at time t2, the reverse current detection circuit 65 asserts the reverse current detection signal INVD to the "H" level. In addition to the parasitic bipolar transistor (first parasitic bipolar transistor) 50, the parasitic bipolar transistor (second parasitic bipolar transistor) 50B also turns on in response to the reverse current Iinv.

Consequently, the parasitic current (first parasitic current) Ipnp flows into the cathode of the temperature detection diode (Di) 13. Additionally, a parasitic current (second parasitic current) Ipnp2, approximately the same magnitude as the parasitic current Ipnp, flows into a cathode of the dummy temperature detection diode 13B. In response, a compensation current Icps, having the same magnitude as the parasitic current Ipnp2, is generated via the current mirror circuit composed of nMOS transistors 28B and 30. Thus, the parasitic current Ipnp flowing into the cathode of the temperature detection diode (Di) 13 is bypassed to the compensation circuit 66C side by the compensation current Icps of equivalent magnitude.

In FIG. 12, during the period from time t2 to time t3, unlike in the case of FIG. 9, the diode current IDi of the temperature detection diode (Di) 13 is maintained at the bias current Ibs. In other words, the influence of the parasitic current Ipnp is eliminated. This allows the over-temperature detection circuit 62 to accurately detect over-temperature even during the period from time t2 to time t3. For example, even if over-temperature occurs in the power transistor (PT) 7 during this period, the control switch 22 can be immediately controlled to turn on, thereby protecting the power transistor (PT) 7.

### Device Configuration of Semiconductor Device

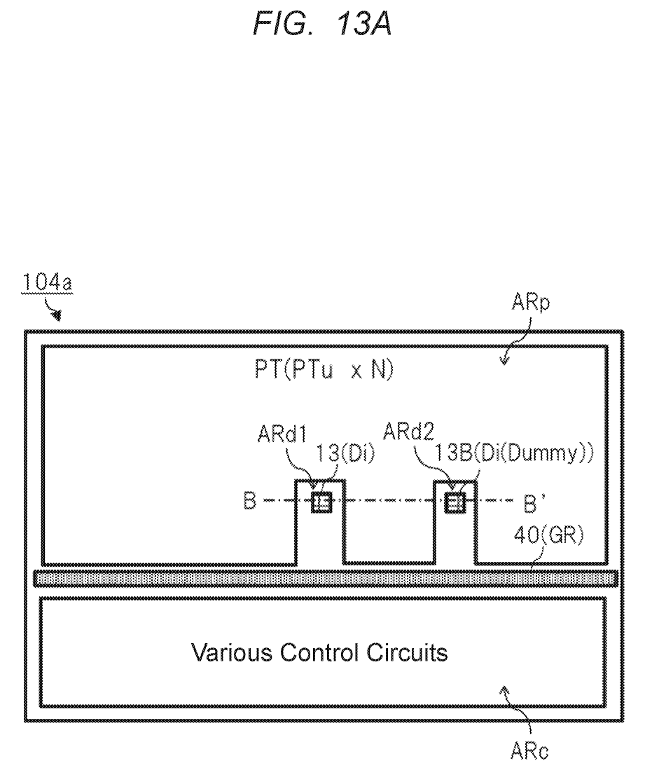

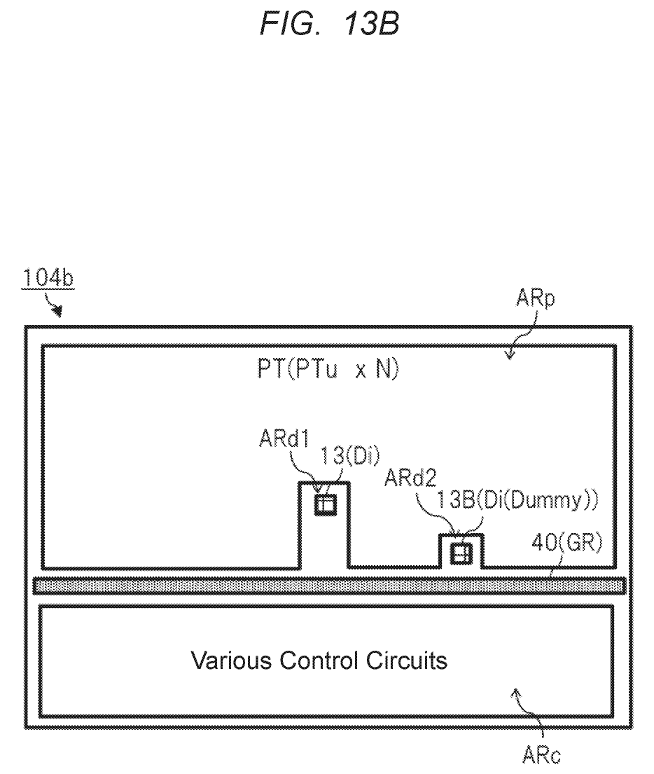

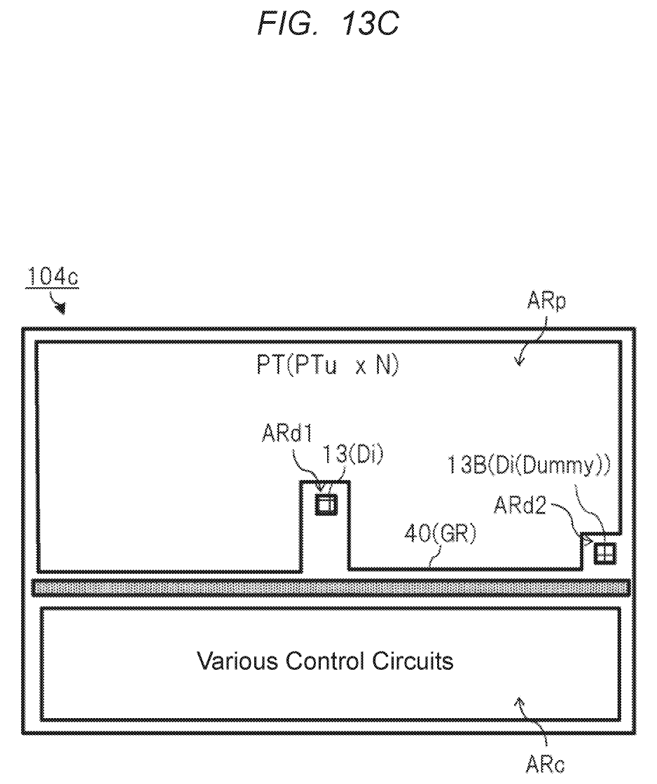

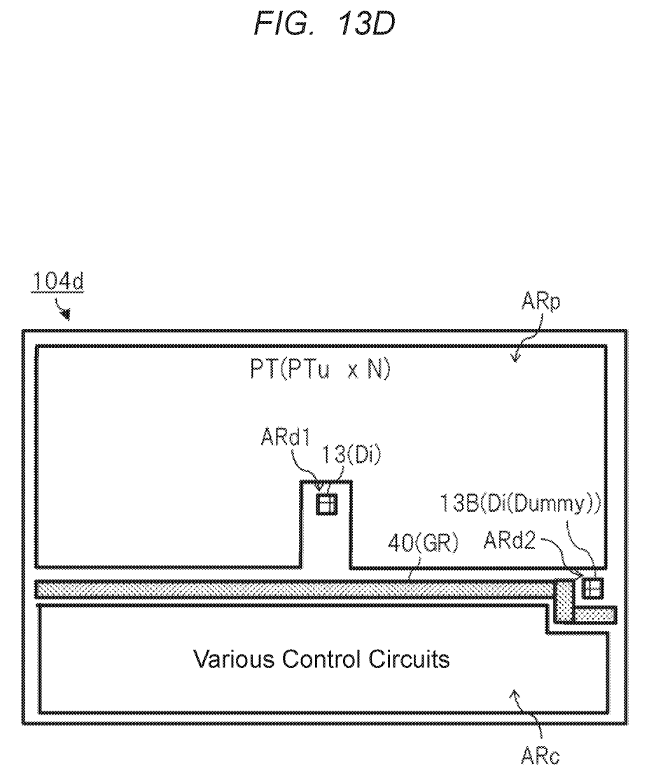

FIGS. 13A, 13B, 13C, and 13D are schematic diagrams showing different layout configuration examples of the semiconductor device 104 in FIG. 11. The semiconductor devices 104a-104d shown in FIGS. 13A to 13D, like in the case of FIG. 2, include the formation region ARp of the power transistor (PT) 7, the formation region ARc of various control circuits, and the guard ring (GR) 40. Furthermore, the semiconductor devices 104a-104d, like in the case of FIG. 2, include a rectangular region (first rectangular region) ARd1 where the temperature detection diode (Di) 13 is formed, and unlike in the case of FIG. 2, also include a rectangular region (second rectangular region) ARd2 where a dummy temperature detection diode 13B is formed.

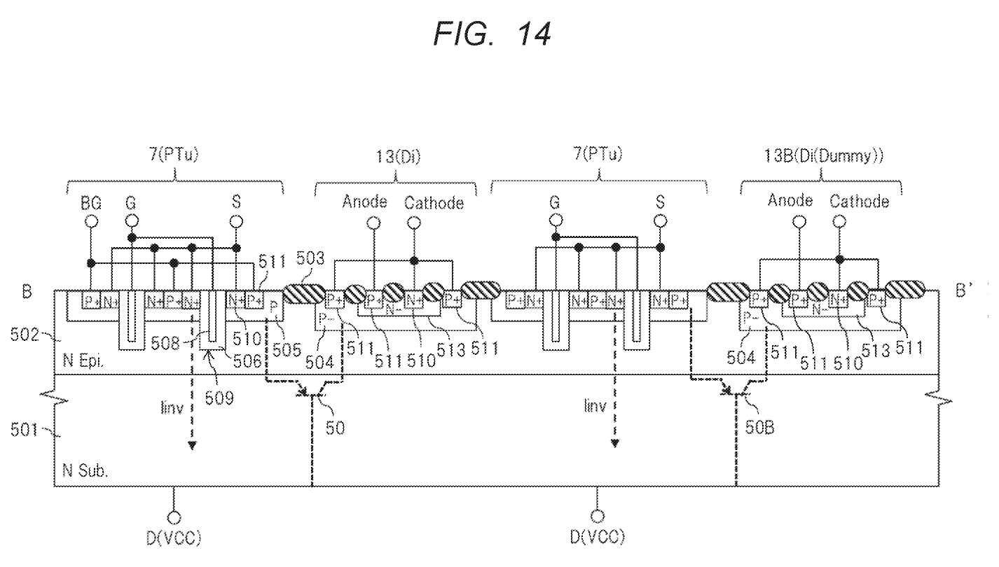

FIG. 14 is a cross-sectional view showing an example of the configuration between B-B' in FIG. 13A. In FIG. 14, a dummy temperature detection diode 13B having the same configuration as the temperature detection diode (Di) 13 is added to the configuration example shown in FIG. 3. In the example shown in FIG. 14, the temperature detection diode (Di) 13 and the dummy temperature detection diode 13B are each arranged adjacent to both sides of the unit output transistor PTu constituting the power transistor (PT) 7.

Here, the semiconductor devices 104a-104d shown in FIGS. 13A to 13D differ from each other in the arrangement of the dummy temperature detection diode 13B. The dummy temperature detection diode 13B is provided to obtain the parasitic current Ipnp2. Therefore, one or more sides constituting the rectangular region ARd2 need to be adjacent to one or more unit output transistors PTu. Also, in the dummy temperature detection diode 13B, it is desirable to obtain the parasitic current Ipnp2 of the same magnitude as the parasitic current Ipnp flowing into the temperature detection diode (Di) 13.

From this perspective, it is desirable that, like the rectangular region ARd1, three sides constituting the rectangular region ARd2 are adjacent to one or more unit output transistors PTu. That is, from this perspective, the arrangements shown in FIGS. 13A and 13B are desirable. For example, one side constituting the formation region ARp, and a side adjacent to the guard ring (GR) 40, is used as a reference side. In this case, the distance between the rectangular region ARd2 and the reference side is the same as that of the rectangular region ARd1 in FIG. 13A, and shorter than that of the rectangular region ARd1 in FIG. 13B. Particularly, using the arrangement shown in FIG. 13A, it is considered that the parasitic current Ipnp2 of the same magnitude as the parasitic current Ipnp can be obtained with high precision.

On the other hand, in FIG. 13C, only two sides constituting the rectangular region ARd2 are adjacent to one or more unit output transistors PTu. Also, in FIG. 13D, only one side constituting the rectangular region ARd2 is adjacent to one or more unit output transistors PTu. In such arrangements, a magnitude of the obtained parasitic current Ipnp2 may be smaller than the required magnitude of the parasitic current Ipnp. However, from the perspective of area efficiency of the power transistor (PT) 7, the arrangements shown in FIGS. 13C and 13D are beneficial.

That is, when arranging the rectangular regions ARd1 and ARd2 inside the formation region ARp, for example, as shown in FIG. 13A, a dead space where no unit output transistor PTu is formed may occur in the area directed from the rectangular regions ARd1 and ARd2 to the reference side. As a result, the number of unit output transistors PTu constituting the power transistor (PT) 7 decreases, and correspondingly, the on-resistance of the power transistor (PT) 7 may increase. In this regard, the arrangement shown in FIG. 13B is more beneficial compared to FIG. 13A.

### Main Effects of the Third Embodiment

As described above, by using the method of the third embodiment, effects similar to those described in the second embodiment can be obtained. Furthermore, compared to the method of the second embodiment, a more precise compensation current Icps can be obtained, allowing for the generation of a more accurate over-temperature detection signal OT1. For example, unlike the method shown in FIG. 10, a high-precision compensation current Icps can be obtained without depending on the current setting resolution in the compensation circuit 66B. Also, even when current value fluctuations of the parasitic current Ipnp occur according to the usage environment of the semiconductor device, a compensation current Icps that follows it can be obtained. Furthermore, the compensation current Icps can be obtained without testing the semiconductor device.

Although the invention made by the inventor has been specifically described based on the embodiment, the present invention is not limited to the embodiment described above, and various modifications can be made without departing from the gist thereof. For example, the embodiment described above is detailed to explain the invention clearly and is not necessarily limited to including all the configurations described. Also, it is possible to replace part of the configuration of one embodiment with the configuration of another embodiment, and it is also possible to add the configuration of another embodiment to the configuration of one embodiment. Additionally, it is possible to add, delete, or replace part of the configuration of each embodiment with other configurations.

What is claimed is:

1. A semiconductor device comprising:
an output transistor formed on a semiconductor substrate, coupled between a power supply terminal and a power output terminal, and configured to supply power to a load coupled to the power output terminal when the output transistor is controlled to be on,
a temperature sensing diode formed on the semiconductor substrate adjacent to the output transistor, and configured to generate a forward voltage with a magnitude reflecting a temperature of the output transistor,
a bias circuit configured to supply a bias current to the temperature sensing diode,
an over-temperature detection circuit configured to detect an over-temperature of the output transistor by comparing the magnitude of the forward voltage with a threshold voltage, and configured to assert a first over-temperature detection signal when the over-temperature is detected,
a reverse current detection circuit configured to detect an occurrence of a reverse current flowing from the power output terminal to the power supply terminal, and configured to assert a reverse current detection signal during a period the reverse current occurs, and
a mask circuit configured to input the reverse current detection signal and the first over-temperature detection signal, and configured to generate a second over-temperature detection signal with a negated level during an assertion period of the reverse current detection signal.

2. The semiconductor device according to claim 1, further comprising:
a control switch configured to control the output transistor to be off during the assertion period of the second over-temperature detection signal.

3. The semiconductor device according to claim 1, wherein the output transistor comprises a plurality of unit output transistors, and the temperature sensing diode is formed in a rectangular region, with two or more sides of the rectangular region adjacent to one or more of the unit output transistors.

4. The semiconductor device according to claim 3, wherein the output transistor is a vertical n-channel MOSFET with a back surface of the semiconductor substrate as a drain, and a source and a drain of the output transistor are coupled to the power output terminal and the power supply terminal, respectively, and
a PNP-type parasitic bipolar transistor is formed between the output transistor and the temperature sensing diode, with a back gate of the output transistor as an emitter and a drain of the output transistor as a base, and configured to turn on by the reverse current.

5. The semiconductor device according to claim 1, wherein the load is a capacitive load or an inductive load.

6. A semiconductor device comprising:
an output transistor formed on a semiconductor substrate, coupled between a power supply terminal and a power output terminal, and configured to supply power to a load coupled to the power output terminal when the output transistor is controlled to be on,
a temperature sensing diode formed on the semiconductor substrate adjacent to the output transistor, configured to generate a forward voltage with a magnitude reflecting a temperature of the output transistor,
a bias circuit configured to supply a bias current to the temperature sensing diode,
a reverse current detection circuit configured to detect an occurrence of a reverse current flowing from the power output terminal to the power supply terminal, and configured to assert a reverse current detection signal during a period the reverse current occurs,
a compensation circuit configured to generate a compensation current and configured to compensate a magnitude of a diode current flowing through the temperature sensing diode using the compensation current during the assertion period of the reverse current detection signal; and
an over-temperature detection circuit configured to detect an over-temperature of the output transistor by comparing the magnitude of the forward voltage with a threshold voltage and configured to assert an over-temperature detection signal when the over-temperature is detected.

7. The semiconductor device according to claim 6, further comprising a control switch configured to control the output transistor to be off during the assertion period of the over-temperature detection signal.

8. The semiconductor device according to claim 6, wherein the output transistor comprises a plurality of unit output transistors, and the temperature sensing diode is formed in the first rectangular region, with two or more sides of the first rectangular region adjacent to one or more of the unit output transistors.

9. The semiconductor device according to claim 8, wherein the output transistor is a vertical n-channel MOSFET with a back surface of the semiconductor substrate as a drain, and a source and a drain of the output transistor are coupled to the power output terminal and the power supply terminal, respectively, and a first PNP-type parasitic bipolar transistor is formed between the output transistor and a cathode of the temperature sensing diode, with a back gate of the output transistor as an emitter and a drain as a base, and configured to be turned on by the reverse current, and a magnitude of the compensation current is determined by reflecting a magnitude of a first parasitic current flowing through the first parasitic bipolar transistor.

10. The semiconductor device according to claim 9, wherein the compensation circuit increases the diode current reduced by the first parasitic current using the compensation current.

11. The semiconductor device according to claim 9, wherein the compensation circuit comprises a variable current source configured to adjust the magnitude of the compensation current, and the magnitude of the compensation current is determined during testing of the semiconductor device.

12. The semiconductor device according to claim 9, wherein the compensation circuit comprises a dummy temperature sensing diode formed on the semiconductor substrate adjacent to the output transistor, and
a second PNP-type parasitic bipolar transistor is formed between the output transistor and a cathode of the dummy temperature sensing diode, and configured to be turned on by the reverse current, and
the compensation circuit is configured to set a second parasitic current flowing through the second parasitic bipolar transistor as the compensation current.

13. The semiconductor device according to claim 12, wherein the dummy temperature sensing diode is formed in a second rectangular region, with one or more sides of the second rectangular region adjacent to one or more of the unit output transistors.

14. The semiconductor device according to claim 6, wherein the load is a capacitive load or an inductive load.
